(19) United States
(12) Patent Application Publication
(10) Pub. No.: US 2006/0076547 A1
(43) Pub. Date: Apr. 13, 2006

(54) Three-dimensional viewing and editing of microcircuit design

(75) Inventors: Yan Lin, Fremont, CA (US); Tsubomi Imamura, San Jose, CA (US)

Correspondence Address: BANNER & WITCOFF, LTD., 1001 G STREET, N.W., WASHINGTON, DC, 20001-4597, US

(73) Assignee: Mentor Graphics Corp., Wilsonville, OR (US)

(21) Appl. No.: 11/236,424

(22) Filed: Sep. 26, 2005

Related U.S. Application Data
(60) Provisional application No. 60/612,878, filed on Sep. 24, 2004.

(51) Int. Cl. H01L 47/00; H01L 29/00

(52) U.S. Cl. 257/1

(57) ABSTRACT

An editing tool that provides a user interface for displaying and editing a representation of a microcircuit design. More particularly, the user interface displays a three dimensional representation of a second portion of the circuit design. A user can then select and edit a structure employing the three-dimensional representation of the structure in the user interface.

### RELATED APPLICATIONS

This application is a continuation-in-part application of U.S. Provisional Patent Application No. 60/612,878, entitled “3D Viewing/Editing System,” filed on Sep. 24, 2004, and naming Yan Lin et al. as inventors, which application is incorporated entirely herein by reference.

### FIELD OF THE INVENTION

The present invention relates to the design of microcircuits. Various aspects of the present invention are particularly applicable to the layout and editing of designs of microcircuit devices.

### BACKGROUND OF THE INVENTION

Microdevices, such as microcircuits formed on a substrate, continue to become more and more complex. A conventional integrated circuit may contain several million transistors, making these devices very difficult to design and fabricate. Moreover, the layout of elements in a microcircuit design typically is not a linear process. Instead, the complexity of laying out the elements of a microcircuit more closely correlates to the formula n log n, where n is the number of elements in the design.

In order to address this complexity, microcircuit designers often will combine several smaller designs in a hierarchical arrangement to form a larger microcircuit design. Typically, each smaller design or “block” describes a group of circuit elements that have been configured to form one or more functional components. In some situations, this block for a group of circuit elements may be new. Frequently, however, a block will be copied from a library of existing designs. For example, rather than creating a new design for a memory device, a circuit designer may simply obtain a previously-created design of a memory device from a library of circuit components, or even a previously-created design for an array of cooperating memory devices. By using these groups or “blocks” of circuit elements that are arranged into one or more functional components, a designer can more easily create a larger microcircuit design to perform a desired task or to have desired features.

During a “floor planning” process, a designer will physically arrange blocks relative to each other for placement on a substrate. More particularly, a designer will create a “floor plan” for the microcircuit design. The floor plan will include the perimeter for the microcircuit design, which will define the size and shape of the microcircuit. It will also include the position of the various contact “pads” required by the microcircuit. These pads, arranged along the periphery the design perimeter, provide connection points for the power, ground, and input/output pins that will connect the microcircuit to a power supply, an electrical ground, and other devices. The blocks of circuit elements are then arranged within the “core” area inside of the contact pads. For some blocks, the shape may be predefined. For other blocks, the shape may not be predefined; the particular height and length of these blocks then may be specified by the designer.

Once the floor plan is created during the “floor planning” process, a designer will then specify the conductive lines to the microcircuit design that will join the blocks of the floor plan. This process often is referred to as the “chip assembly” process. During this process, for example, the designer will route the conductive lines or “wires” that will connect the circuitry of each block to a power supply and a ground connection. The designer also will route the wires that will carry command and data signals to and from the circuitry in each block. The designer also may add one or more guard bands to the microcircuit design. As known in the art, a guard band is a barrier of conductive material used to shield circuit elements from electromagnetic interference.

Routing for electrical connection wires may generally be categorized into two steps: global routing and detailed (or “local”) routing. Global routing defines the overall directions in which the wires are laid out to avoid large structures. Detailed routing then specifies the local detours for the wires that are taken along those general directions to avoid other wires or smaller structures. Various errors can be introduced into the wiring process. For example, a designer may erroneously specify the location of structure, such as the placement of a via between incorrect metal layers. Further, a designer may inadvertently omit a structure, such as a portion of a guard band from a metal layer, or erroneously include an undesired structure. Moreover, even if the location of a structure is properly specified in a design, the properties of that structure (e.g., its width, height, length, or distance from another structure) may violate one or more predetermined design rules for that microcircuit design.

Accordingly, a designer will typically need to edit the conductive lines of a microcircuit design before the design is finished. To address this need, various software providers have created circuit design editing tools, such as Virtuoso and Apollo. These conventional editing tools provide a graphical user interface that renders a two dimensional image of the structure described in a microcircuit design. Each metal layer in the design typically is rendered with a different color, and a designer can select a layer in the design by using a pointing device. For example, the designer may select a layer by using a pointing device to move a cursor over the visual representation of that layer in the two dimensional image, and then activating a selection button (i.e., by “clicking” on the desired layer). The designer can then edit the portion of the design describing the selected layer using conventional editing commands.

While these conventional editing tools continue to be used, they are not very practical for editing complex modern circuit designs. When most circuit designs included only two or three metal layers, a circuit designer may have an easier time distinguishing the colors of each layer. A modern circuit design, however, may have as many as nine metal layers vertically stacked on top of each other, and future circuit designs may have even more. It is difficult to distinguish between these layers when viewed in a two dimensional image, as the colors of two adjacent layers blend together to create a third color. To edit a structure, the designer therefore must sequentially select and hide each layer above the desired layer, until the desired layer of material is the uppermost layer displayed in the two dimensional image. Only after the desired layer is uppermost in the image can the designer accurately select the particular structure to be edited. This process is tedious and time consuming. Moreover, the images of the layers below the desired layer may still distract a designer from clearly distinguishing features in the desired layer of material.

Conventional editing tools are often particularly difficult to use for locating and correcting design rule violations. In some cases, the feature causing the violation actually may be located between layers of material, making the violation especially difficult to identify using a two dimensional editing tool. As a result, design rule verification often is the most time-consuming part of a circuit layout process.

### BRIEF SUMMARY OF THE INVENTION

Various aspects of the invention advantageously provide a tool that a designer may employ to edit a circuit design. More particularly, various examples of the invention provide a tool that renders at least a portion of a circuit design using a three dimensional image. The three dimensional rendering of the circuit design portion allows a circuit designer to easily distinguish between layers. Rather than having to hide each layer occurring above a desired structure, a designer can, for example, move a cursor directly over a portion of the desired layer or even over a particular structure in order to select that layer or structure.

With some embodiments of the invention, for example, an editing tool may provide two user interfaces. The first user interface will display a two dimensional representation of a first portion of a circuit design, while the second user interface displays a three dimensional representation of a second portion of the circuit design. In some implementations of the invention, the first portion of the circuit design may be the same as the second portion of the circuit design. With other implementations of the invention, however, the second portion of the circuit design may be a subset or even a superset of the first portion of the circuit design. Still further, a user may employ the two dimensional representation of the circuit design portion displayed in the first user interface to select which portion of the circuit design will be rendered with a three dimensional representation in the second user interface.

### BRIEF DESCRIPTION OF THE DRAWINGS

FIG. 1 illustrates an example of a programmable computer that can be used to implement various embodiments of the invention.

FIG. 2 schematically illustrates a three-dimensional circuit design viewing and editing tool according to various embodiments of the invention.

FIGS. 3A-3D illustrate examples of user interfaces that may be provided by a viewing and editing tool according to various embodiments of the invention.

FIGS. 4A-4C illustrate a flowchart showing the operation of a viewing and editing tool according to various embodiments of the invention.

### DETAILED DESCRIPTION OF THE INVENTION

Overview

Various aspects of the invention relate to the three dimensional display of an integrated circuit design. By rendering the features of an integrated circuit design in a three dimensional view, implementations of the invention allow a circuit designer to clearly distinguish those features, even if they occur across multiple layers of material. A design can thus more accurately analyze and edit the circuit design. For example, if a designer wishes to view or edit a particular structure in an integrated circuit design, the designer does not have to hide each layer of material occurring in the design above the structure. Instead, the designer can view or edit the structure directly in the three-dimensional view.

Operating Environment

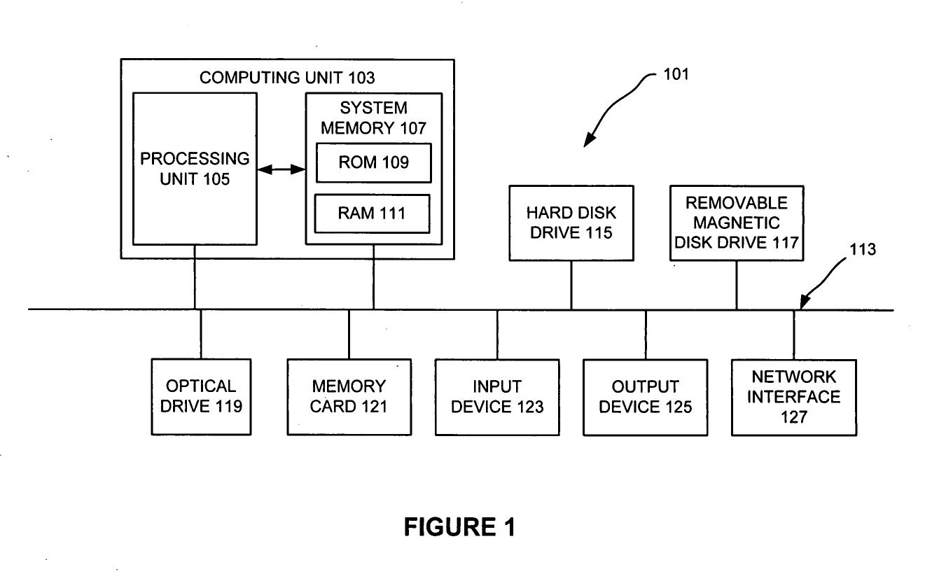

An editing and viewing tool according to various embodiments of the invention may be implemented through the execution of software instructions by a computing device, such as a programmable computer. An illustrative example of such a computing device 101 is illustrated in FIG. 1. As seen in this figure, the computing device 101 has a computing unit 103. The computing unit 103 typically includes a processing unit 105 and a system memory 107. The processing unit 105 may be any type of processing device for executing software instructions, but will conventionally be a microprocessor device. The system memory 107 may include both a read-only memory (ROM) 109 and a random access memory (RAM) 111. As will be appreciated by those of ordinary skill in the art, both the read-only memory (ROM) 109 and the random access memory (RAM) 111 may store software instructions for execution by the processing unit 105.

The processing unit 105 and the system memory 107 are connected, either directly or indirectly, through a bus 113 or an alternative communication structure, to one or more peripheral devices. For example, the processing unit 105 or the system memory 107 may be directly or indirectly connected to one or more additional memory storage devices, such as a hard disk drive 115, a removable magnetic disk drive 117, an optical disk drive 119, or a flash memory card 121. The processing unit 105 and the system memory 107 also may be directly or indirectly connected to one or more input devices 123 and one or more output devices 125. The input devices 123 may include, for example, a keyboard, a pointing device (such as a mouse, touchpad, stylus, trackball, or joystick), a scanner, a camera, and a microphone. The output devices 125 may include, for example, a monitor display, a printer and speakers.

With some implementations, the computing unit 103 may be directly or indirectly connected to one or more network interfaces 127 for communicating with a network. The network interface 127 translates data and control signals from the computing unit 103 into network messages according to one or more communication protocols, such as the transmission control protocol (TCP) and the Internet protocol (IP). These protocols are well known in the art, and thus will not be discussed here in more detail. An interface 127 may employ any suitable connection agent (or combination of agents) for connecting to a network, including, for example, a wireless transceiver, a modem, or an Ethernet connection.

It should be appreciated that one or more of these peripheral devices may be housed with the computing unit 103 and bus 113. Alternatively or additionally, one or more of these peripheral devices may be housed separately from the computing unit 103 and bus 113, and then connected (either directly or indirectly) to the bus 113. Also, it should be appreciated that both computers and computing appliances may include any of the components illustrated in FIG. 1, may include only a subset of the components illustrated in FIG. 1, or may include an alternative combination of components, including some components that are not shown in FIG. 1.

A Circuit Design Viewing and Editing Tool

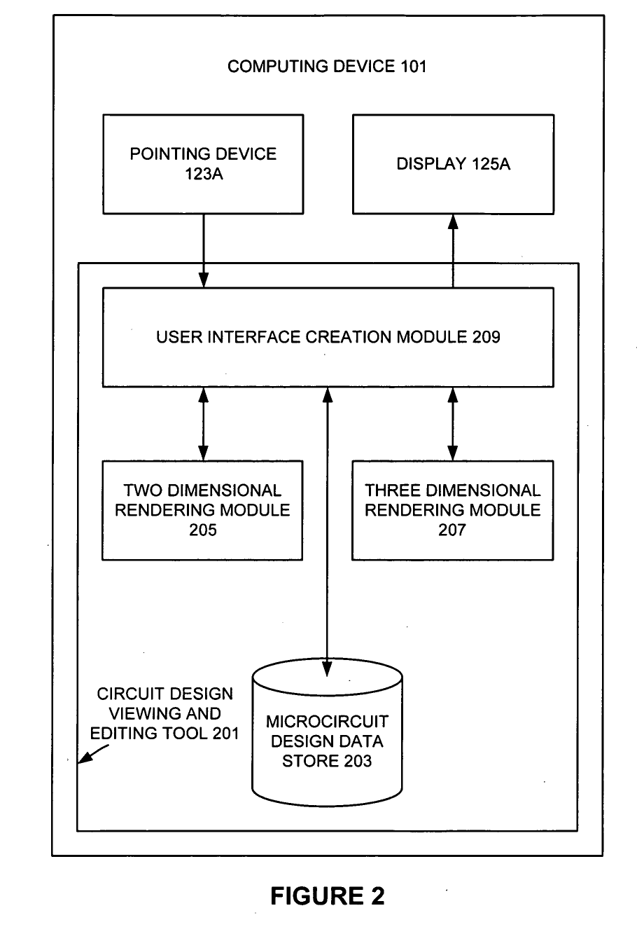

FIG. 2 schematically illustrates a circuit design viewing and editing tool 201 that may be implemented according to various embodiments of the invention. As seen in this figure, the tool 201 includes a microcircuit design storage module 203, a two-dimensional rendering module 205, a three-dimensional rendering module 207, and a user interface creation module 209. As previously noted, each of these modules may be implemented by a set of software instructions stored on a storage medium that can be executed by a programmable computer, through the execution of such software instructions by a programmable computer, by the storage of data on a storage medium, or a combination thereof.

The microcircuit design storage module 203 stores one or more designs for a microcircuit. Typically, these circuit designs will describe the various structures making up a circuit based upon the layer in which each structure occurs. For example, for a circuit having five metals layers, the design will have five different groups of data with each group defining the structure in a corresponding metal layer. The structures in each layer may then be defined using, for example, a Cartesian coordinate system.

A microcircuit design in the microcircuit design storage module 203 may include one or more existing circuit design layouts that already contain blocks representing one or more components of the microcircuit. Alternatively, these floor plan designs may include a blank template to which a designer can add blocks during a design process. In addition to the layout of the blocks, a design may also include the layout of various other features of the microcircuit, such as the routing of various connection wires associated with the blocks. For example, a microcircuit design may include features of power and ground wires, such as power/ground network wires, that will provide electrical power to the components of the circuit.

A microcircuit design may alternatively or additionally include features for one or more signal wires that will transmit clocking, control and/or data signals to and from the microcircuit components. Alternatively or additionally, a designer may wish to include one or more individual signal wires carrying critical signals in a microcircuit design, to ensure that these signal wires are optimally routed. Of course, any desired feature of a circuit design may be included in a microcircuit design according to various embodiments of the invention.

A microcircuit design data may be created or stored in any conventional data format that will represent the desired microcircuit structures. For example, various embodiments of the invention can maintain and manipulate the microcircuit design in any convenient design data format, such as the Library Exchange Format/Design Exchange Format (LEF/DEF), the Open Access database format, or the Milkyway data format, each of which are well known in the art, and thus will not be discussed here in further detail. Still other embodiments of the invention may alternatively or additionally employ more complex formats (i.e., formats that provide additional information unnecessary for maintaining and manipulating a microcircuit design), such as the GDS II data format or the OASIS data format. With these embodiments, the circuit design and editing tool 201 may continuously maintain a microcircuit design in a more complex data format, or convert a more complex data format into a simpler, more convenient design data format for viewing and manipulation, such as those listed above. Still other embodiments of the invention may convert a microcircuit design from a simpler, more convenient design data format into a more complex data format for manufacturing or final verification of the microcircuit design.

The user interface creation module 209 provides one or more user interfaces to allow a designer to view and edit a microcircuit design stored in the microcircuit design storage module 203. For example, the user interface creation module 209 may create a graphical user interface that allows a user to view a list of the microcircuit designs stored in the microcircuit design storage module 203, and then to select one or more of the microcircuit designs from the list for viewing in the graphical user interface. Of course, any other desired techniques may be used to retrieve a desired microcircuit design from the floor plan design storage module. The user interface creation module 209 will then create one or more user interfaces for displaying representations of the selected microcircuit design.

For example, the user interface creation module 209 will employ the two dimensional rendering module 205 to create a first user interface displaying a two-dimensional image of at least a portion of the selected microcircuit design. More particularly, the two-dimensional rendering module 205 will create a two dimensional image corresponding to the structure described in each layer of at least a portion of the microcircuit design. The two-dimensional rendering module 205 will then superimpose the image representing the highest layer over the image representing the next highest layer until all of the layers are displayed by the first user interface. Various techniques for creating such a two-dimensional representation of microcircuit design data are well known in the art, and therefore will not be further described.

As will be discussed in more detail below, the user interface creation module 209 also will employ the three-dimensional rendering module 207 to display a three-dimensional image of at least a portion of the selected microcircuit design in a second user interface. For example, the three-dimensional rendering module 207 may modify the Cartesian x-y coordinate values describing the structures in a material layer to include a common z-coordinate value. By selecting sequential z-coordinate values for each separate layer of material, the three-dimensional rendering module 207 can create three dimensional coordinate data describing a three-dimensional representational of the circuit design, which can then be rendered by the user interface creation module 209 in the second user interface. Various techniques for rendering such a three-dimensional representation are well known in the art, and therefore will not be further described.

In addition to visually displaying the integrated circuit design, the user interface creation module 209 may also receive selection data for selecting features of a displayed integrated circuit design for editing or other type of manipulation. For example, the first or second interface (or both) may accept input data from, e.g., the pointing device 123 as selection data to select one or more features of the integrated circuit design displayed in that user interface. The circuit design viewing and editing tool 201 may then provide additional command buttons or other controls that will allow a user to perform a desired edit or other manipulation of the selected feature.

With some embodiments of the invention, the user interface creation module 209 may additionally synchronize selection data received through the first and second user interfaces. Thus, a designer may select a structure using the second user interface (that is, the user interface displaying the three-dimensional representation of the circuit). In response, the three-dimensional rendering module 207 changes the appearance of the structure displayed in the second user interface, to confirm to the designer that this structure has been selected. The user interface creation module 209 will then instruct the two-dimensional rendering module 205 to change the appearance of that structure in the first user interface as well, to visually indicate its selection in both user interfaces.

For example, a designer may use a pointing device to position a cursor over the three-dimensional rendering of a circuit structure in the second user interface. When the user selects the structure by, e.g., activating a selection command button (sometimes referred to as “clicking” on the structure), the user interface creation module 209 determines the Cartesian coordinates of the selected structure, including its z-coordinate value. Based upon this z-coordinate value, the user interface creation module 209 determines the layer of the circuit in which the selected structure is formed. Thus, the user interface creation module 209 can identify both the selected structure and the layer in which the structure is formed. Using this information, the user interface creation module 209 can then have the two-dimensional rendering module 205 change the appearance of the two-dimensional representation structure in the first user interface. In the same manner, the user interface creation module 209 ensures that a structure selected through the first user interface is likewise selected in the second user interface.

The user interface creation module 209 may also synchronize editing data between the first and second user interfaces. As previously described, a designer may select a structure for editing through the second user interface. In response to edit inputs, the user interface creation module 209 makes the appropriate change to the appearance of the circuit design in both the first user interface and second user interface. For example, if the selected structure is a via, the designer may execute one or more edit commands to delete the via. In response, the user interface creation module 209 will have the two-dimensional rendering module 205 delete the via from the two-dimensional representation of the circuit design in the first user interface. The user interface creation module 209 also will have the three-dimensional rendering module 207 delete the via from the three-dimensional representation of the circuit design in the second user interface.

Similarly, if the selected structure is a conductive line, the designer may execute one more edit commands to lengthen or shorten the line. In response, the user interface creation module 209 will have the two-dimensional rendering module 205 lengthen or shorten the conductive line in the two-dimensional representation of the circuit design in the first user interface, and have the three-dimensional rendering module 207 lengthen or shorten the three-dimensional representation of the circuit design in the second user interface. In this manner, a designer can select and edit a structure using either the two-dimensional representation of the circuit design rendered in the first user interface or the three-dimensional representation of the circuit design rendered in the second user interface.

With the embodiments of the invention described above, both selection and edit data submitted in one user interface are mirrored in the other user interface. It should be appreciated, however, that alternative embodiments of the invention may only show edit data only in the user interface receiving the selection or edit data. With these embodiments, selection data submitted in one user interface may not be reflected in the other user interface.

It also should be appreciated that, with some embodiments of the invention, edit changes to the circuit design may be made directly in the microcircuit design storage module 203. With still other embodiments of the invention, however, edit changes to the circuit design may be made only to a duplicate cache of the design data. Thus, while a designer may view the design modifications made by the edit changes in the user interfaces, the designer can discard the modifications before permanently changing the circuit design. If the designer does decide to make the modifications permanent, then the user may, for example, activate a save command to relay the edit changes from the duplicate cache to the microcircuit design storage module 203.

User Interfaces Provided by a Circuit Design Viewing and Editing Tool

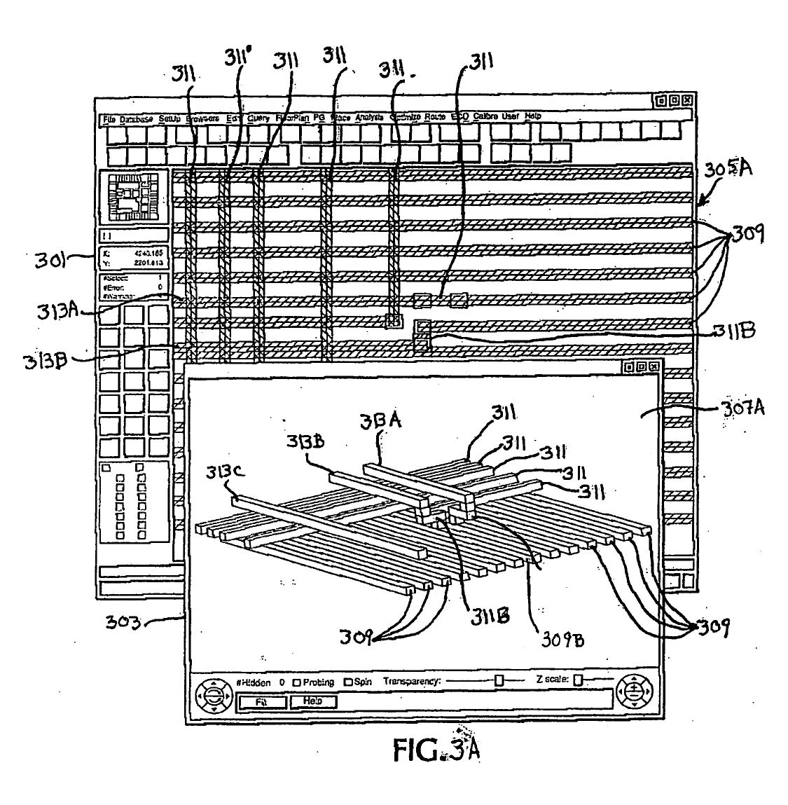

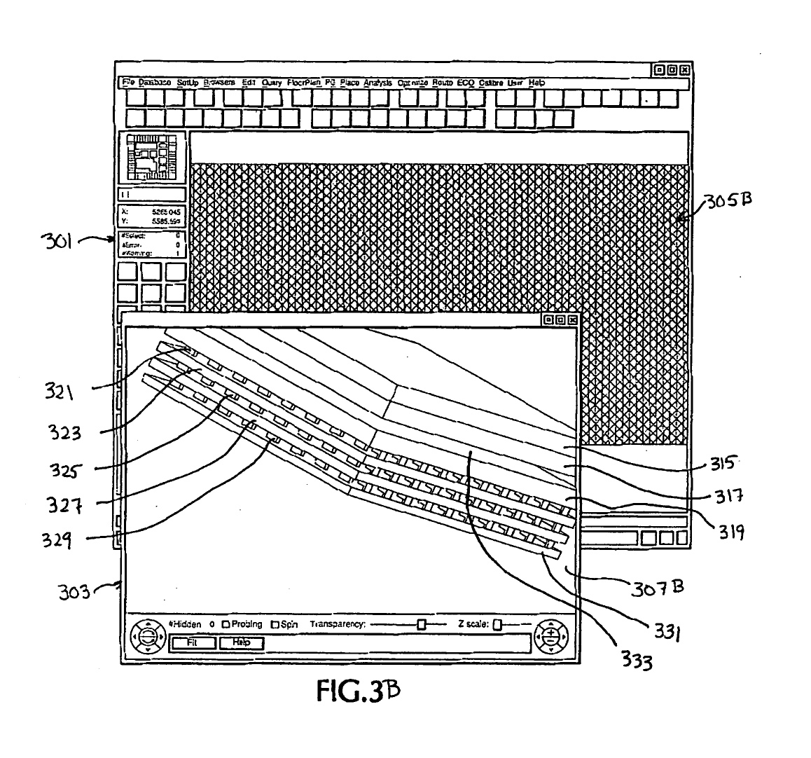

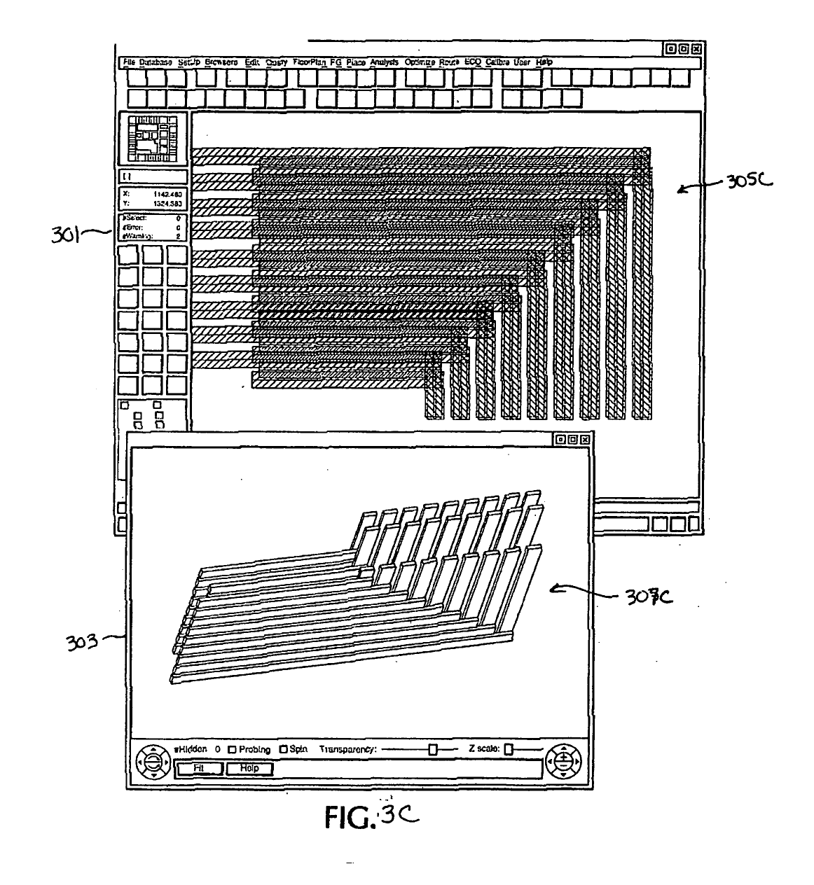

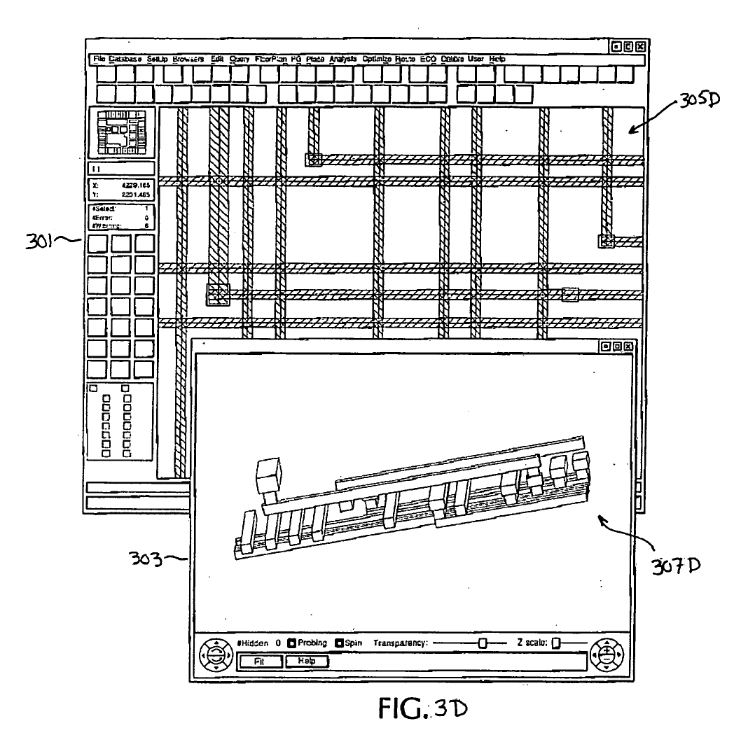

FIG. 3 illustrates an example of a first user interface 301 and a second user interface 303 that may be provided by a circuit viewing and editing tool 201 according to various embodiments of the invention. The first interface 301 displays a two-dimensional representation 305A of a circuit design portion, while the second interface 303 displays a three-dimensional representation 307A of the circuit design portion. As seen in this figure, the circuit design portion includes a plurality of conductive lines 309 formed in a lower metal layer and running in a first direction. The circuit design portion also includes a plurality of conductive lines 311 formed in a middle metal layer and running in a second direction orthogonal to the first direction. Still further, the circuit design portion also includes a plurality of conductive lines 313 formed in an upper metal layer and running in the first direction as well. It should be appreciated that the conductive lines 309-313 can be seen in both the two-dimensional representation 305 and the three-dimensional representation 307.

The circuit design portion shown in this figure has two redundant vias. For example, rather than having a single via connect upper conductive line 313A directly to lower conductive line 309A, the design portion instead has a first via connecting upper conductive line 313A to middle conductive line 311A, and a second via connecting middle conductive line 311A to the lower conductive line 309A. Similarly, rather than having a single via connect upper conductive line 313B directly to lower conductive line 309B, the design portion instead has a first via connecting upper conductive line 313B to middle conductive line 311B, and a second via connecting middle conductive line 311B to the lower conductive line 309B. Thus, one via in each of these routes from upper conductive line 313 to lower conductive line 309 is redundant.

Accordingly, a designer would normally wish to replace the two vias connecting upper conductive line 313A to lower conductive line 309A with a single via directly between the conductive line 313A in the upper metal layer and the conductive line 309A in the lower metal layer. Likewise, a designer would normally wish to replace the two vias connecting upper conductive line 313B to lower conductive line 309B with a single via directly between the conductive line 313B and the conductive line 309B. In order to make these replacements, however, the designer would first need to realize that the design portion included the redundant vias. As seen in this figure, however, the redundant routing between upper conductive line 313B and lower conductive line 309B cannot easily be distinguished in the two-dimensional representation 305 of the circuit design portion. Moreover, because conductive lines 309A-313A run parallel to each other in a vertical direction, the redundant routing between upper conductive line 313A and lower conductive line 309A is extremely difficult to identify in the two-dimensional representation 305 of the circuit design portion.

As shown in the user interface 303, however, the three-dimensional representation of the circuit design portion according to the invention clearly reveals both redundant via structures. Moreover, the designer can easily use the three-dimensional representation of the circuit design to select and edit each of conductive lines 309A-313A, 309B-313B, and their interconnecting vias. Thus, by employing the three-dimensional representation 307 of the circuit design portion, a designer can easily recognize the redundant routing. Moreover, the designer can conveniently select the conductive lines and the vias in order to edit the design portion and replace the redundant routing.

FIG. 3B illustrates another example of how various examples of the invention can be used to view and edit an integrated circuit design. As seen in this figure, the first interface 301 displays a two-dimensional representation 305 of a second circuit design portion (which may be, for example, from a new circuit design or another portion of the circuit design partially illustrated in FIG. 3A), while the second interface 303 displays a three-dimensional representation 307B of the second circuit design portion. As seen in this figure, the second circuit design portion defines a guard band structure. More particularly, the design portion includes a plurality of stacked material layers 315-331. As seen in the user interface 303, however, the design portion has an empty area 333 between material layers 317 and 319. Thus, the design portion is missing the description of the structure for an entire layer of material, which presents a significant error in the design.

As will be appreciated from this figure, the empty space 333 indicating the missing material layer cannot be seen in the two-dimensional display 305B of the design portion. This missing layer may be readily identified, however, from the three-dimensional display 307B of the design portion in user interface 303. Thus, a design can quickly identify and correct this error in the design using the three-dimensional display 307B, whereas the designer might overlook the error entirely using only the two-dimensional display 305B of the design portion.

FIGS. 3C and 3D further illustrate examples of how portions of an integrated circuit design might be displayed in a three-dimensional view according to various embodiments of the invention. More particularly, FIG. 3C illustrates an example of the user interface 301 displaying a third circuit design portion in a two-dimensional view 305C, while the user interface 303 displays the third circuit design portion in a three-dimensional view 307C. Similarly, FIG. 3D illustrates an example of the user interface 301 displaying a fourth circuit design portion in a two-dimensional view 305D, while the user interface 303 displays the fourth circuit design portion in a three-dimensional view 307C. As seen from these figures, the three-dimensional rendering of the design portions allow a designer to more efficiently and accurately identify and edit discrete features of the design.

Example Operation of a Circuit Design Viewing and Editing Tool

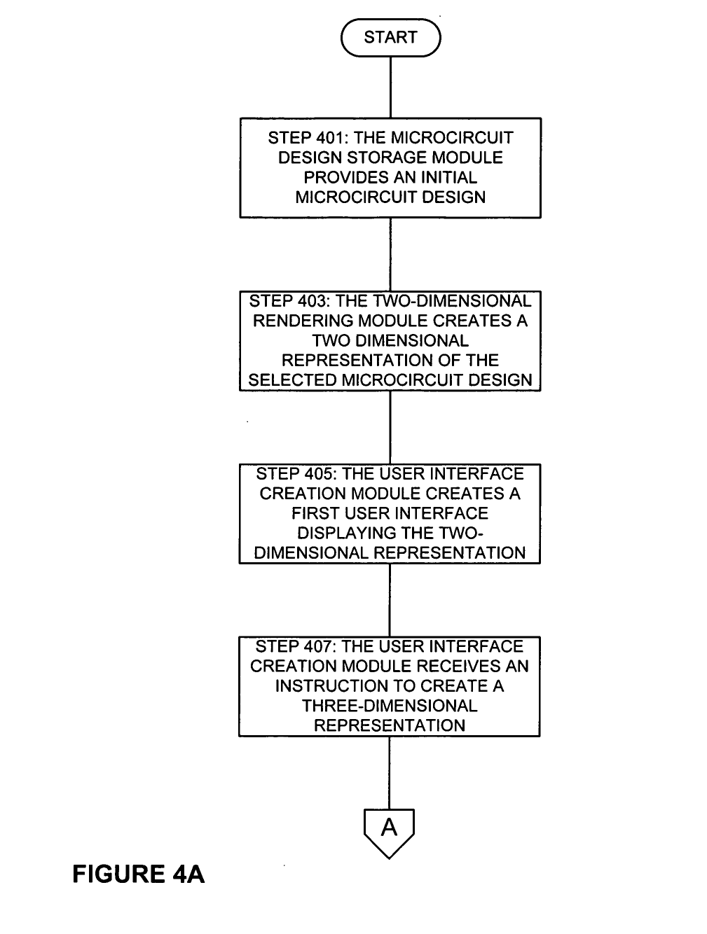

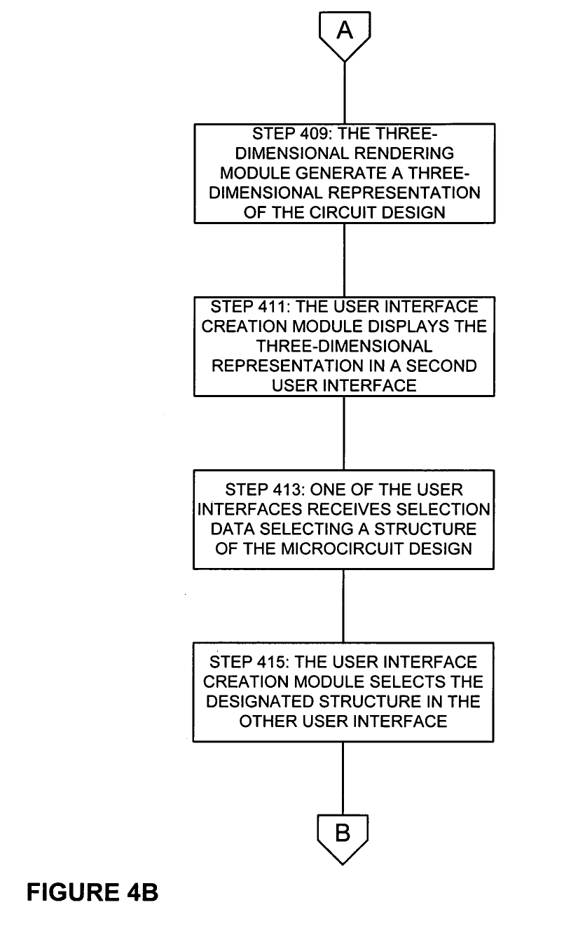

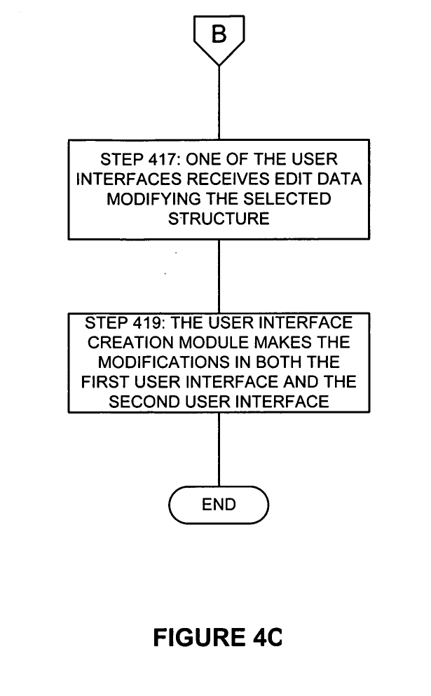

The operation of various embodiments of the invention will now be described with reference to the flowchart illustrated in FIGS. 4A-4C. When the tool 201 is initiated, the microcircuit design storage module 203 provides an initial microcircuit design to the user interface creation module 209 in step 401. For example, user interface creation module 209 may generate an initial user interface, such as the first user interface 301 shown in FIGS. 3A-3D, which provides a menu for selecting among one or more microcircuit designs stored in the microcircuit design storage module 203. The designer can then select a desired microcircuit design using the menu. In response, the user interface creation module 209 will have the two-dimensional rendering module 205 create a two dimensional representation of at least a portion of the selected microcircuit design in step 403. Next, in step 405, the user interface creation module 209 will create a first user interface, such as the user interface 301 shown in FIGS. 3A-3D, which displays the two-dimensional representation of the microcircuit design.

With various embodiments of the invention, a designer can view and edit the selected microcircuit design using only the two-dimensional representation of the circuit design shown in the first user interface. If, however, the designer wishes to view a three-dimensional representation of the circuit design, then the designer can employ the second user interface to display the three-dimensional representation of the circuit design. For example, the first user interface may include a command button for instructing the user interface creation module 209 to create the second user interface. Alternatively, some embodiments of the invention may automatically have the user interface creation module 209 create the second user interface concurrently with the first user interface.

Accordingly, in step 407, the user interface creation module 209 receives an instruction to create a three-dimensional representation of the circuit design. In response, the user interface creation module 209 has the three-dimensional rendering module 207 generate a three-dimensional representation of the circuit design in step 409. In step 411 the user interface creation module 209 then displays the three-dimensional representation of the circuit design in a second user interface, such as the user interface 303 shown in FIG. 3.

It should be appreciated that, with some circuit designs, the entire design may be too large to be displayed in its entirety in either the first user interface or the second user interface. Accordingly, with various embodiments of the invention, the two-dimensional representation of the circuit design may actually be a representation of only a portion of the entire circuit design. The first user interface may therefore include one or more commands or functions to allow a user to select which portion of the microcircuit design for which a two-dimensional representation will be displayed in the first user interface.

Similarly, the three-dimensional representation of the circuit design may actually be a representation of only a portion of the circuit design. For some embodiments of the invention, the portion of the microcircuit design shown in the second user interface will be the same portion of the microcircuit design shown in the first user interface. With still other implementations of the invention, however, the portion of the microcircuit design shown in the second user interface may be different from the portion of the microcircuit design shown in the first user interface. For example, the portion of the microcircuit design shown in the second user interface may be a subset or a superset of the portion of the microcircuit design shown in the first user interface. Accordingly, the first or second interface also may provide one or more commands or functions for selecting which portion of the microcircuit design will be rendered in the second user interface.

With various embodiments of the invention, the user interface creation module 209 may have the first and second user interfaces display only those features of the initial microcircuit design (or portion of a microcircuit design) selected by a user. For example, with these embodiments, a user may instruct the user interface creation module 209 to display only the blocks of the initial microcircuit design, to display the blocks along with the power network wiring and the ground network wiring for the microcircuit design, to display one or more of the signal bus wires for the microcircuit design, to display the guard bands for the design, or to display any combination of these or other desired items. In some embodiments of the invention, the user interface creation module 209 may selectively filter features of the initial microcircuit design from being displayed in one or both of the user interfaces. With still other embodiments of the invention, however, the user interface creation module 209 may only receive the desired portions of the initial microcircuit design from the microcircuit design storage module 203 for display.

In order to properly render the two-dimensional representation and the three-dimensional representation of the circuit design in the user interfaces, the two-dimensional rendering module 205, the three-dimensional rendering module 207 and the user interface creation module 209 may include various application programming interfaces or other components necessary to create graphic images corresponding to the microcircuit plan design. Also, while the two-dimensional rendering module 205, the three-dimensional rendering module 207, and the user interface creation module 209 are illustrated as being a part of the viewing and editing tool 201, with alternative embodiments of the invention one or more functions of these modules may be performed by external software applications, such as the operating system for the computing device 101. The display 125A may be any desired type of display including, for example, a cathode ray tube display, a plasma screen display, or a liquid crystal display (LCD).

When a designer wishes to modify the initial microcircuit plan design (or create a new microcircuit design from a blank template), the user can control the information graphically displayed in the user interfaces by, for example, manipulating one or more of the input devices 123, such as the pointing device 123A. The pointing device 123A may be any desired pointing device, such as a keyboard, a mouse, a touchpad, a joystick, a stylus operating with a digitizer, or a combination of two or more pointing devices. As discussed above, a designer may control the user interface to select and edit a structure in the initial microcircuit design. For example, a designer may use the pointing device 123A to select a “target” structure, and then subsequently employ a pointing device to edit one or more characteristics of that structure.

Thus, once the microcircuit design is displayed in both the first user interface and the second user interface, in step 413 one of the user interfaces will receive selection data selecting a structure of the microcircuit design. Next, in step 415, the user interface creation module 209 selects that structure in the other user interface. In step 417, one of the user interfaces will then receive edit data modifying the selected structure. In step 419, the user interface creation module 209 will make the specified modifications to the representation of the structure in both the two-dimensional representation of the circuit design in the first user interface and the three-dimensional representation of the circuit design in the second user interface. In this manner, a designer can more accurately view and edit a microcircuit design.

Alternative Examples of the Invention

While specific examples of a circuit design viewing and editing tools according to different embodiments of the invention have been described in detail above, it should be appreciated that there are variety of alternative embodiments of the invention. For example, while various implementations of the circuit design viewing and editing tools discussed above display a two-dimensional representation of a circuit design, other implementations of a circuit design viewing and editing tools according to various embodiments of the invention may omit a two-dimensional display of the circuit design. These tools may instead display only a three-dimensional representation of a circuit design, or display a two-dimensional representation of a circuit design only when specifically instructed by a user. Still other examples of the invention may only allow a designer to view a three-dimensional representation of a circuit design, without allowing a designer to edit the design using the three-dimensional representation.

Conclusion

Accordingly, various embodiments of the invention provide a tool for viewing a three-dimensional display of a circuit design, and employing that three-dimensional display to edit the circuit design. While the invention has been described with respect to specific examples including presently preferred modes of carrying out the invention, those skilled in the art will appreciate that there are numerous variations and permutations of the above described systems and techniques that fall within the spirit and scope of the invention.

What is claimed is:

1. A method for displaying a design for a microcircuit, comprising:
receiving at least a portion of a microcircuit design; and
rendering a three-dimensional representation of the at least a portion of the microcircuit design.

2. The method for displaying a design for a microcircuit recited in claim 1, further comprising:
receiving an entire microcircuit design; and
receiving design selection input selecting the at least a portion of the microcircuit design.

3. The method for displaying a design for a microcircuit recited in claim 1, further comprising:
receiving structure selection input selecting a structure described in the at least a portion of the microcircuit design; and
indicating selection of the selected structure in the rendered three-dimensional representation of the at least a portion of the microcircuit design.

4. The method for displaying a design for a microcircuit recited in claim 3, further comprising:
receiving edit selection input defining changes to be made to the selected structure
editing the rendered three-dimensional representation of the at least a portion of the microcircuit design to incorporate the changes defined in the edit selection input.

5. The method for displaying a design for a microcircuit recited in claim 3, further comprising:
receiving at least a portion the structure selection input as pointer position input in the rendered three-dimensional representation of the at least a portion of the microcircuit design; and
cross-referencing the pointer position input with- the rendered three-dimensional representation of the at least a portion of the microcircuit design to determine the structure in the selected section of the microcircuit design to be selected.

6. The method for displaying a design for a microcircuit recited in claim 1, further comprising:
identifying a violation of a design rule in the at least a portion of the microcircuit design; and
rendering a marker in the rendered three-dimensional representation of the at least a portion of the microcircuit design corresponding to the identified design rule violation.

7. A microcircuit design tool, comprising:
a memory containing a microcircuit design; and
a three-dimensional rendering module that renders a three-dimensional representation of at least a portion of the microcircuit design.

8. The microcircuit design tool recited in claim 7, further comprising a design edit module that
receives structure selection input selecting a structure described in the at least a portion of the microcircuit design; and
provides the selected structure to the three-dimensional rendering module for rendering an indicator identifying the selected structure in the rendering of the three-dimensional representation of the at least a portion of the microcircuit design.

9. The microcircuit design tool recited in claim 8, wherein the design edit module
receives edit selection input defining changes to the selected structure; and
provides the defined changes to the three-dimensional rendering module for incorporation into the rendering of the three-dimensional representation of the at least a portion of the microcircuit design.

10. The microcircuit design tool recited in claim 8, wherein the design edit module
receives at least a portion the structure selection input as pointer position input in the rendering of three-dimensional representation of the at least a portion of the microcircuit design; and
cross-references the pointer position input with the rendering of the three-dimensional representation of the selected section of the microcircuit design to determine a structure in the selected section of the microcircuit design to be selected.

11. The microcircuit design tool recited in claim 7, further comprising:
a violation identification module that identifies a violation of a design rule in the at least a portion of the microcircuit design; and
wherein the three-dimensional rendering module renders a marker in the rendering of the a three-dimensional representation of the at least a portion of the microcircuit design corresponding to the identified design rule violation.

12. A method of correcting a flaw in an integrated circuit design, comprising:
selecting an integrated circuit design;
displaying a three-dimensional representation of at least a portion of an integrated circuit design;
viewing the three-dimensional representation of the at least a portion of the integrated circuit design to identify at least one flaw in the at least a portion of the integrated circuit design; and
correcting the identified at least one flaw in the integrated circuit design to produce a corrected integrated circuit design.

13. The method of correcting a flaw in an integrated circuit design recited in claim 12, wherein the flaw is an omission of a structure from the integrated circuit design.

14. The method of correcting a flaw in an integrated circuit design recited in claim 12, wherein the flaw is a redundant structure in the integrated circuit design.

15. The method of correcting a flaw in an integrated circuit design recited in claim 12, wherein the flaw is a design rule violation.

16. The method of correcting a flaw in an integrated circuit design recited in claim 12, further comprising manufacturing an integrated circuit from the corrected integrated circuit design.

17. A corrected integrated circuit design produced using the method of correcting a flaw in an integrated circuit design recited in claim 12.

18. A method for displaying a design for a microcircuit, comprising:
receiving first design selection input selecting at least a portion of a microcircuit design;
rendering a two-dimensional representation of the selected portion of the microcircuit design;
receiving second design selection input selecting a section of the microcircuit design within the selected portion of the microcircuit design;
in response to receiving the second selection input, rendering a three-dimensional representation of the selected section of the microcircuit design.

19. The method for displaying a design for a microcircuit recited in claim 18, wherein the first selection input and the second selection input are the same input.

20. The method for displaying a design for a microcircuit recited in claim 18, further comprising:
receiving structure selection input selecting a structure described in the selected section of the microcircuit design;
receiving edit selection input defining changes to the selected structure;
rendering a new two-dimensional representation of the selected portion of the microcircuit design incorporating the changes defined in the edit selection input; and
rendering a new three-dimensional representation of the selected section of the microcircuit design incorporating the changes defined in the edit selection input.

21. The method for displaying a design for a microcircuit recited in claim 20, further comprising editing the selected section of the microcircuit design to incorporate the changes defined in the edit selection input.

22. The method for displaying a design for a microcircuit recited in claim 20, further comprising:
receiving at least a portion the structure selection input as pointer position input in the two-dimensional representation of the selected section of the microcircuit design; and
cross-referencing the pointer position input with the rendering of the two-dimensional representation of the selected section of the microcircuit design to determine a structure in the selected section of the microcircuit design to be selected.

23. The method for displaying a design for a microcircuit recited in claim 20, further comprising:
receiving at least a portion the structure selection input as pointer position input in the three-dimensional representation of the selected section of the microcircuit design; and
cross-referencing the pointer position input with the rendering of the three-dimensional representation of the selected section of the microcircuit design to determine a structure in the selected section of the microcircuit design to be selected.

24. The method for displaying a design for a microcircuit recited in claim 18, further comprising:
identifying a violation of a design rule in the selected section of the microcircuit design; and
rendering a marker in the three-dimensional representation of the selected section of the microcircuit design corresponding to the identified design rule violation.

25. A microcircuit design tool, comprising:
a memory containing a microcircuit design;
a two-dimensional rendering module that renders a two-dimensional representation of at least a portion of the microcircuit design; and
a three-dimensional rendering module that renders a three-dimensional representation of a section of the microcircuit design within the portion of the microcircuit design.

26. The microcircuit design tool recited in claim 25, further comprising a design edit module that
receives structure selection input selecting a structure described in the selected section of the microcircuit design;
receives edit selection input defining changes to the selected structure;
provides the defined changes to the two-dimensional rendering module for incorporation into a two-dimensional representation of the portion of the microcircuit design; and
provides the defined changes to the three-dimensional rendering module for incorporation into a three-dimensional representation of the section of the microcircuit design.

27. The microcircuit design tool recited in claim 26, wherein the design edit module
receives at least a portion the structure selection input as pointer position input in the two-dimensional representation of the selected section of the microcircuit design; and
cross-references the pointer position input with the rendering of the two-dimensional representation of the selected section of the microcircuit design to determine a structure in the selected section of the microcircuit design to be selected.

28. The microcircuit design tool recited in claim 26, wherein the design edit module
receives at least a portion the structure selection input as pointer position input in the three-dimensional representation of the selected section of the microcircuit design; and
cross-references the pointer position input with the rendering of the three-dimensional representation of the selected section of the microcircuit design to determine a structure in the selected section of the microcircuit design to be selected.

29. The microcircuit design tool recited in claim 25, further comprising:
a violation identification module that identifies a violation of a design rule in the selected section of the microcircuit design; and
wherein the three-dimensional rendering module renders a marker in a three-dimensional representation of the selected section of the microcircuit design corresponding to the identified design rule violation.
